(19) United States
(12) Patent Application Publication
(10) Pub. No.: US 2024/0250497 A1
(43) Pub. Date: Jul. 25, 2024

(54) LIGHT EMITTING DEVICE

(71) Applicant: NICHIA CORPORATION, Anan-shi (JP)

(72) Inventor: Tadayuki KITAJIMA, Itano-gun (JP)

(73) Assignee: NICHIA CORPORATION, Anan-shi (JP)

(21) Appl. No.: 18/417,032

(22) Filed: Jan. 19, 2024

(30) Foreign Application Priority Data
Jan. 25, 2023 (JP) 2023-009403

(51) Int. Cl. H01S 5/0225; H01S 5/0232; H01S 5/40

(52) U.S. Cl. CPC H01S 5/0225; H01S 5/40; H01S 5/0232

(57) ABSTRACT

A light emitting device includes: a base having a recess and a flat upper surface; a light emitting element disposed on the upper surface of the base and configured to emit light laterally from an emission end surface; and a reflective member disposed on the upper surface of the base to face the light emitting element with the recess located between part of the reflective member and the light emitting element in a top view, the reflective member having a reflective surface configured to reflect the light upward. At least a portion of the reflective surface overlaps with the recess in the top view. A lower end of the reflective surface is located lower than the upper surface of the base and higher than a bottom surface of the recess in a direction normal to the upper surface of the base.

### CROSS-REFERENCE TO RELATED APPLICATIONS

This application is based on and claims priority to Japanese Patent Application No. 2023-009403, filed on Jan.25, 2023, the entire contents of which are incorporated herein by reference.

### TECHNICAL FIELD

The present disclosure relates to a light emitting device.

### BACKGROUND

Japanese Patent Publication No. 2021-90044 describes a laser device that includes a substrate, a laser oscillation unit, and a reflective member. In the laser device, the substrate has a principal surface and a recess provided in the principal surface, the laser oscillation unit is fixed to the principal surface and has an emission surface from which laser light is emitted along the principal surface, and the reflective member is fixed to the bottom surface of the recess and has an inclined surface that is inclined with respect to the principal surface and that is positioned so as to reflect the laser light.

In the laser device, the laser oscillation unit and the reflective member are disposed on the different surfaces of the substrate. Thus, variations in height from the bottom surface to the principal surface affect the mounting positions of the laser oscillation unit and the reflective member.

### SUMMARY

According to the present disclosure, it is an object to provide a light emitting device in which a light emitting element and a reflective member can be arranged with high accuracy.

A light emitting device according to an embodiment of the present disclosure includes a base having a recess and an upper surface that is a flat surface; a light emitting element disposed on the upper surface of the base and configured to emit light laterally from an emission end surface; and a reflective member that is disposed on the upper surface of the base to face the light emitting element with the recess interposed between the reflective member and the light emitting element, and that has a reflective surface configured to reflect the light upward. At least a portion of the reflective surface overlaps with the recess in a top view. A lower end of the reflective surface is located lower than the upper surface of the base and higher than a bottom surface of the recess in a direction normal to the upper surface of the base.

### BRIEF DESCRIPTION OF THE DRAWINGS

Other objects and further features of the present invention will be apparent from the following detailed description when read in conjunction with the accompanying drawings, in which:

FIG. 1 is a perspective view of a light emitting device according to a first embodiment;

FIG. 2 is a perspective view of the light emitting device illustrated in FIG. 1, from which lateral walls and a cover are removed;

FIG. 3 is a top view of the light emitting device illustrated in FIG. 1, from which the lateral walls and the cover are removed;

FIG. 4 is a cross-sectional view of the light emitting device taken through a cross-sectional line IV-IV of FIG. 1;

FIG. 5 is a bottom view of the light emitting device according to the first embodiment;

FIG. 6 is a top view illustrating metal films provided on a base and via wirings provided in the base;

FIG. 7 is a perspective view of a reflective member according to an embodiment;

FIGS. 8A and 8B are cross-sectional views (part 1) illustrating a manufacturing method of a reflective member according to the embodiment;

FIGS. 9A and 9B are cross-sectional views (part 2) illustrating the manufacturing method of the reflective member according to the embodiment;

FIG. 10 is an enlarged cross-sectional view of a light emitting element, the reflective member, and their surroundings in the light emitting device illustrated in FIG. 4;

FIG. 11 is a perspective view of a light emitting device according to a second embodiment;

FIG. 12 is a perspective view of the light emitting device illustrated in FIG. 11, from which lateral walls and a cover are removed;

FIG. 13 is a top view of the light emitting device illustrated in FIG. 11, from which the lateral walls and the cover are removed;

FIG. 14 is a cross-sectional view of the light emitting device taken through a cross-sectional line XIV-XIV of FIG. 11; and

FIG. 15 is a bottom view of the light emitting device according to the second embodiment.

### DETAILED DESCRIPTION

Embodiments of the present invention will be described below with reference to the accompanying drawings. In the following description, terms indicating specific directions and positions (for example, “upper”, “upward”, “lower”, “downward” and other terms including or related to these terms) are used as necessary. These terms are used to facilitate understanding of the present invention with reference to the drawings, and the technical scope of the present invention is not unduly limited by the meaning of these terms. For example, the term “upper surface” does not necessarily mean that the “upper surface” must face upward at all times. The same reference numerals appearing in a plurality of drawings refer to the same or similar portions or members.

In the present disclosure, the term “polygonal shape” such as a triangular shape and a quadrangular shape encompasses polygonal shapes in which corners of the polygonal shapes are rounded, chamfered, beveled, coved, and the like. Furthermore, the term “polygonal shape” not only encompasses polygonal shapes in which corners (ends of sides) are processed, but also encompasses polygonal shapes in which intermediate portions of the sides are processed. In other words, shapes that are based on polygonal shapes and partially processed are construed as “polygonal shapes” as described in the present disclosure.

The same applies not only to polygonal shapes, but also to terms indicating specific shapes such as trapezoidal shapes, circular shapes, and projections and recesses. The same also applies when referring to sides forming such a shape. In other words, even if a corner or an intermediate portion of a side is processed, the “side” is construed as including the processed portion. In order to distinguish a “polygonal shape” or a “side” that is not partially processed from a processed shape, such a shape may be expressed with the word “strict” added thereto, for example, a “strict quadrangular shape”.

Further, the following embodiments exemplify light emitting devices and the like to embody the technical idea of the present invention, and the present invention is not limited to the following description. In addition, unless otherwise specified, the dimensions, materials, shapes, relative arrangements, and the like of components described below are not intended to limit the scope of the present invention thereto, but are described as examples. The contents described in one embodiment can be applied to other embodiments and modifications. The sizes, positional relationships, and the like of members illustrated in the drawings may be exaggerated for clearer illustration. Furthermore, to avoid excessive complication of the drawings, a schematic view in which some elements are not illustrated may be used, or an end view illustrating only a cut surface may be used as a cross-sectional view.

### First Embodiment

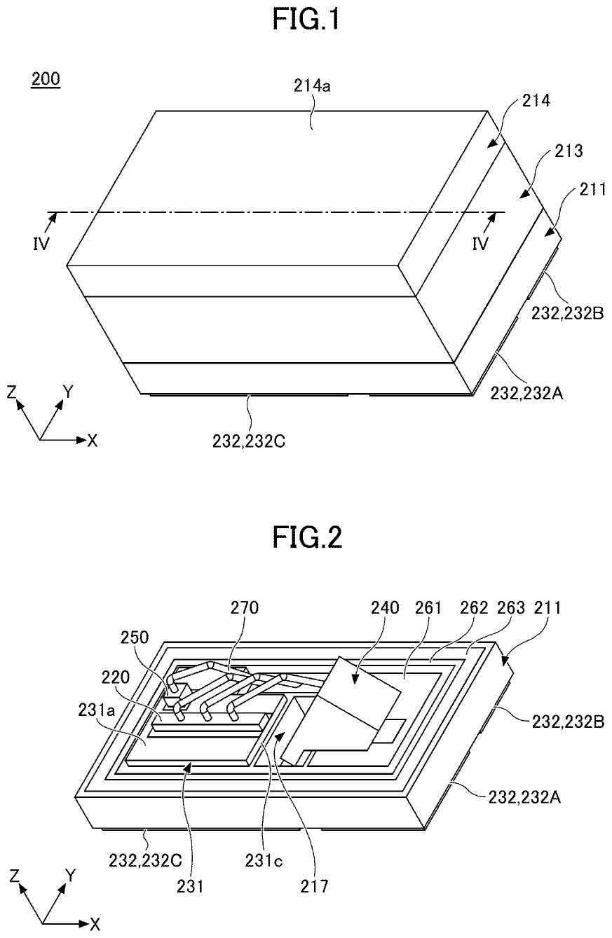

A light emitting device according to a first embodiment includes a base, a light emitting element, and a reflective member. An example structure of a light emitting device 200 according to the first embodiment will be described with reference to FIG. 1 through FIG. 7.

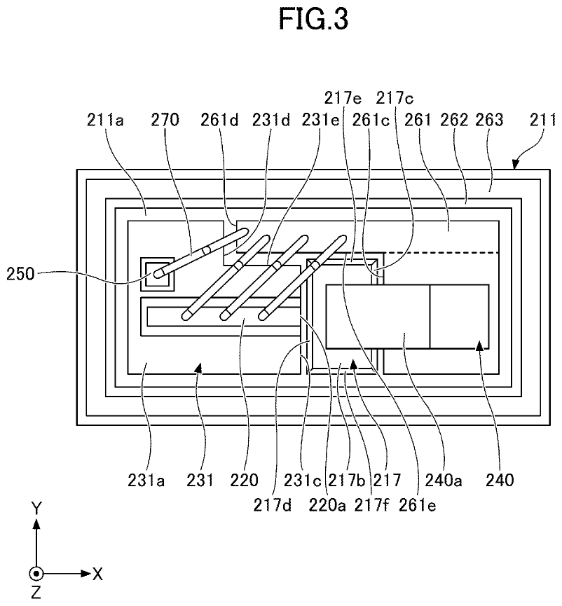

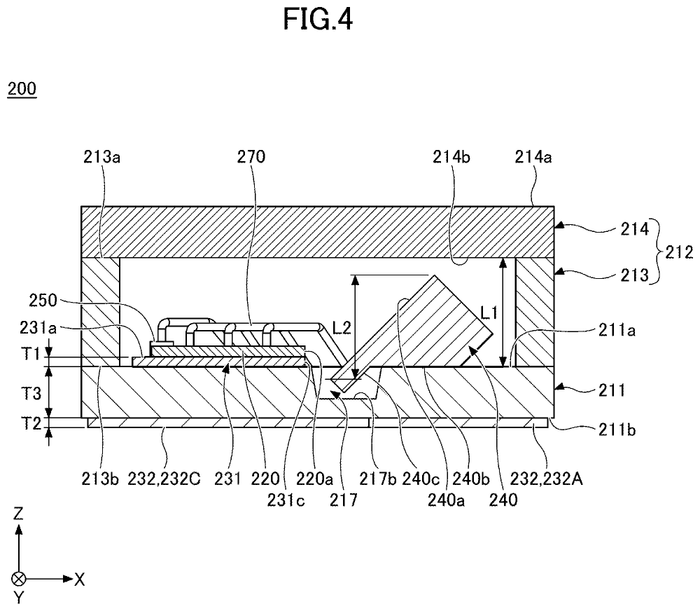

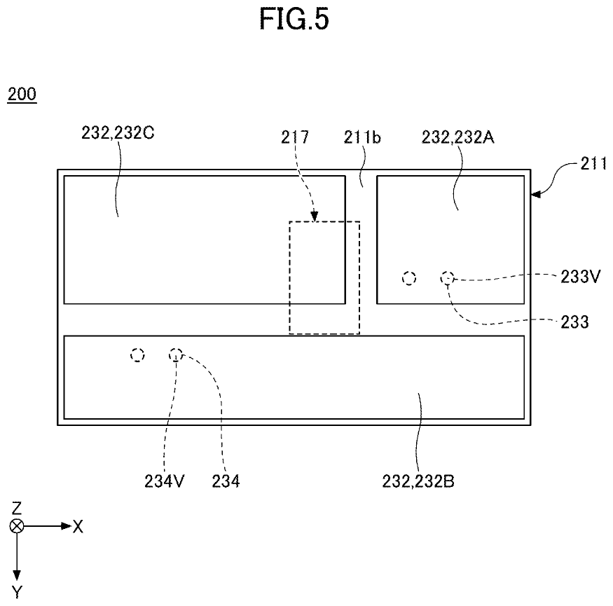

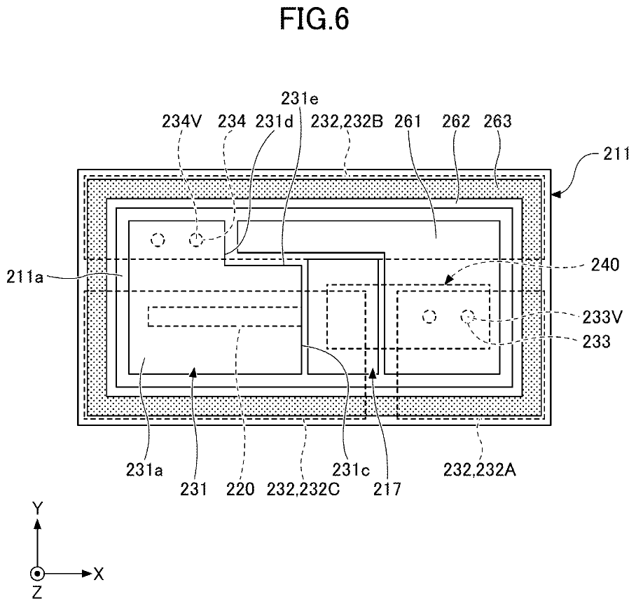

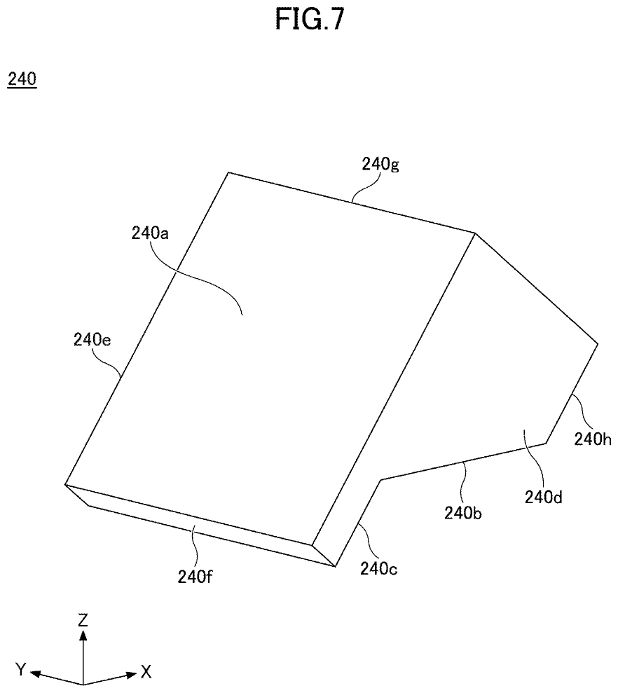

FIG. 1 is a perspective view of the light emitting device 200 according to the first embodiment. FIG. 2 is a perspective view of the light emitting device 200 illustrated in FIG. 1, from which lateral walls 213 and a cover 214 are removed. FIG. 3 is a top view of the light emitting device 200 illustrated in FIG. 1, from which the lateral walls 213 and the cover 214 are removed. FIG. 4 is a cross-sectional view of the light emitting device 200 taken through a cross-sectional line IV-IV of FIG. 1. FIG. 5 is a bottom view of the light emitting device 200 according to the first embodiment. FIG. 6 is a top view illustrating metal films provided on a base 211 and via wirings provided in the base 211. FIG. 7 is a perspective view of a reflective member 240 according to the first embodiment.

The light emitting device 200 according to the present embodiment includes the base 211, a light emitting element 220, a metal part 231, lower metal parts 232, and the reflective member 240. In the illustrated example, the light emitting device 200 further includes the lateral walls 213, the cover 214, a protective element 250, and wirings 270. The light emitting device 200 does not necessarily include all of the above components.

The components of the light emitting device 200 will be described. The metal part 231 and the lower metal parts 232 of the light emitting device 200 will be described together with the base 211.

In FIG. 1 through FIG. 7, an X-axis, a Y-axis, and a Z-axis orthogonal to one another are illustrated for reference. Directions parallel to the X-axis, the Y-axis, and the Z-axis are defined as a first direction X, a second direction Y, and a third direction Z, respectively. The first direction X and the second direction Y are parallel to an upper surface 211a of the base 211, and the third direction Z is perpendicular to the upper surface 211a of the base 211.

### (Base 211, Metal Part 231, and Lower Metal Parts 232)

The base 211 has the upper surface 211a, a lower surface 211b, and a recess 217. The upper surface 211a is a flat surface. In the illustrated example, the lower surface 211b is a flat surface, but the lower surface 211b is not necessarily a flat surface. The upper surface 211a and the lower surface 211b are parallel to each other, for example. As used herein, the term “parallel” with respect to the surfaces of the base 211 includes a tolerance of ±5 degrees. The recess 217 is open to the upper surface 211a. The recess 217 is defined by a bottom surface 217b and one or more lateral surfaces. The one or more lateral surfaces of the recess 217 meet the upper surface 211a and extend downward from the upper surface 211a. The shape of the recess 217 in a top view is, for example, a rectangle, and the length of the rectangle in the second direction Y is greater than the length of the rectangle in the first direction X.

In the illustrated example, edges at which the one or more lateral surfaces of the recess 217 meet the upper surface 211a of the base 211 are defined as edges 217c, 217d, 217e, and 217f. In the present specification, two edges opposite to each other in the first direction X and extending in the second direction Y are the edges 217c and 217d. Of them, the edge 217c is located on the positive side in the first direction X. Further, two edges opposite to each other in the second direction Y and extending in the first direction X are the edges 217e and 217f. Of them, the edge 217e is located on the positive side in the second direction Y.

The surface roughness of the bottom surface 217b may be greater than the surface roughness of the upper surface 211a. The one or more lateral surfaces of the recess 217 are inclined with respect to the bottom surface 217b. The inclination angle of the one or more lateral surfaces with respect to the bottom surface 217b is, for example, 60 degrees or more and 90 degrees or less. The one or more lateral surfaces of the recess may be perpendicular to the bottom surface 217b.

Further, the base 211 has one or more lateral surfaces connected to the upper surface 211a and the lower surface 211b. The one or more lateral surfaces connect the outer edge of the upper surface 211a and the outer edge of the lower surface 211b. The base 211 is, for example, a rectangular parallelepiped or a cube. In this case, each of the upper surface 211a and the lower surface 211b of the base 211 has a rectangular shape, and the base 211 has four lateral surfaces each having a rectangular shape. The term “rectangular shape” may include a square shape unless specifically described to exclude a square shape. The base 211 is not necessarily a rectangular parallelepiped or a cube. For example, the base 211 may have any plate shape in a top view. The shape of the base 211 in a top view is not limited to a plate shape, and the base 211 may have any shape, such as a circular shape, an elliptical shape, or a polygonal shape in a top view.

The base 211 includes a material having, for example, an insulating property. The base 211 can be formed of ceramic as the main material. For example, aluminum nitride, silicon nitride, aluminum oxide, or silicon carbide may be used as the ceramic. The main material forming the base 211 may be an electrically conductive material. Examples of the main material of the base 211 include metal such as aluminum, gold, silver, copper, tungsten, iron, nickel, cobalt, and an alloy thereof, diamond, a copper-diamond composite material, and the like.

The metal part 231 is provided on the upper surface 211a of the base 211. The material forming the metal part 231 may be, for example, copper. Other examples of the material forming the metal part 231 include copper-tungsten. A thickness T1 of the metal part 231 is less than a thickness T3 of the base 211. The thickness T1 of the metal part 231 is, for example, 30 μm or more and 120 μm or less. By setting the thickness of the metal part 231 to be within the above range, heat generated from the light emitting element 220 can be efficiently dissipated by the metal part 231.

The metal part 231 is provided close to one short side of two short sides opposite to each other in the long side direction of the upper surface 211a in a top view. More specifically, of the two short sides of the upper surface 211a, the metal part 231 is provided close to the negative side in the first direction X. In the illustrated example, the metal part 231 has a projecting shape in a top view. More specifically, the metal part 231 has a projecting portion that projects toward the center of the upper surface 211a in the long side direction of the upper surface 211a (in the first direction) in a top view. For the sake of description, a portion of the metal part 231 that is recessed toward the negative side in the first direction X relative to the projecting portion in a top view is referred to as a recessed portion. In the illustrated example, a lateral surface 231c of the projecting portion is located closer to the center of the upper surface 211a than the lateral surface 231d of the recessed portion is. The metal part 231 may have a rectangular shape in a top view.

The projecting portion and the recessed portion of the metal part 231 will be further described. The metal part 231 has a lateral surface 231e connected to the lateral surface 231c and the lateral surface 231d. The projecting portion of the metal part 231 is the entire portion including the side surface 231c with respect to a straight line that passes along the lateral surface 231e and is parallel to the lateral surface 231e in a top view. The recessed portion of the metal part 231 is the entire portion including the lateral surface 231d with respect to the straight line that passes along the lateral surface 231e and is parallel to the lateral surface 231e in a top view.

The length of the projecting portion of the metal part 231 is greater than the length of the recessed portion of the metal part 231 in the long side direction of the upper surface 211a (in the first direction X). The length of the recessed portion of the metal part 231 is 0.2 times or more and 0.7 times or less the length of the projecting portion of the metal part 231 in the long side direction of the upper surface 211a. Further, the length of the projecting portion of the metal part 231 is greater than the length of the recessed portion of the metal part 231 in the short side direction of the upper surface 211a (in the second direction Y). The length of the recessed portion of the metal part 231 is 0.3 times or more and 0.7 times or less the length of the projecting portion of the metal part 231 in the short side direction of the upper surface 211a.

A metal film 261 may be further provided on the upper surface 211a of the base 211. In a top view, the metal film 261 is spaced apart from the metal part 231. The thickness of the metal film 261 is preferably less than one-third of the thickness T1 of the metal part 231 in the third direction Z.

In the long side direction of the upper surface 211a (in the first direction X), the metal film 261 is provided close to one short side opposite to the other short side close to which the metal part 231 is provided. Further, the metal film 261 is provided opposite to the metal part 231 with the recess 217 interposed therebetween.

In the illustrated example, the metal film 261 has a projecting shape that projects toward the metal part 231 (toward the negative side) in the first direction X in a top view. For the sake of description, a portion of the metal film 261 that is recessed relative to the projecting portion in a top view is referred to as a recessed portion. In the example illustrated in FIG. 3, the boundary between the recessed portion and the projecting portion of the metal film 261 is indicated by a dashed line. In a top view, the projecting portion of the metal part 231 and the recessed portion of the metal film 261 face each other in the first direction X with the recess 217 interposed therebetween. In a top view, the recessed portion of the metal part 231 and the projecting portion of the metal film 261 face each other in the first direction X. No recess 217 is provided between the recessed portion of the metal part 231 and the projecting portion of the metal film 261. More specifically, the lateral surface 231c of the metal part 231 faces the edge 217d of the recess 217 in a top view. A side 261c of the recessed portion of the metal film 261 faces the edge 217c of the recess 217. A side 261e of the projecting portion of the metal film 261 faces the edge 217e of the recess 217 and the lateral surface 231e of the metal part 231. Further, the lateral surface 231d of the metal part 231 faces a side 261d of the metal film 261. The projecting portion of the metal film 261 is provided near one edge of the two edges of the recess 217 that are opposite to each other in the second direction Y. The projecting portion of the metal film 261 is not provided near the other edge of the two edges. In the illustrated example, relative to the recess 217, the projecting portion of the metal film 261 is provided on the positive side in the second direction Y and is not provided on the negative side in the second direction Y.

One or more lower metal parts 232 may be provided on the lower surface 211b of the base 211. When the lower metal parts 232 are provided on the lower surface 211b of the base 211, a thickness T2 of the one or more lower metal parts 232 is less than the thickness T3 of the base 211. Further, the thickness T2 of each of the lower metal parts 232 is preferably 0.8 times or more and 1.2 times or less the thickness T1 of the metal part 231. Accordingly, the imbalance of stress between the upper surface 211a side and the lower surface 211b side of the base 211 can be reduced, and thus, the base 211 is less likely to be warped. The thickness T2 of each of the lower metal parts 232 is, for example, 25 μm or more and 150 μm or less.

In the illustrated example, the one or more lower metal parts 232 include a first lower metal part 232A, a second lower metal part 232B, and a third lower metal part 232C. As illustrated in FIG. 5, in a bottom view, one of the four corners of the first lower metal part 232A is located at or near one of the four corners of the lower surface 211b having a rectangular shape. More specifically, the first lower metal part 232A is located on the positive side in the first direction X and the negative side in the second direction Y on the lower surface 211b. In a bottom view, the second lower metal part 232B has a rectangular shape whose side extending in the long side direction of the lower surface 211b is longer than the side extending in the short side direction of the lower surface 211b. The second lower metal part 232B is disposed on the positive side in the second direction Y relative to the first lower metal part 232A. In a bottom view, the first lower metal part 232A and the second lower metal part 232B are spaced apart from each other in the short side direction of the lower surface 211b (in the second direction Y). The second lower metal part 232B is longer than the first lower metal part 232A in the long side direction of the lower surface 211b (in the first direction X). Further, the second lower metal part 232B is shorter than the first lower metal part 232A in the short side direction of the lower surface 211b (in the second direction Y).

In a bottom view, the third lower metal part 232C is spaced apart from the first lower metal part 232A in the long side direction of the lower surface 211b (in the first direction X), and the third lower metal part 232C is spaced apart from the second lower metal part 232B in the short side direction of the lower surface 211b (in the second direction Y). More specifically, the third lower metal part 232C is disposed on the negative side in the first direction X relative to the first lower metal part 232A, and is disposed on the negative side in the second direction Y relative to the second lower metal part 232B. In a bottom view, the third lower metal part 232C is shorter than the second lower metal part 232B and is longer than the first lower metal part 232A in the long side direction of the lower surface 211b (in the first direction X). Further, the third lower metal part 232C is longer than the second lower metal part 232B in the short side direction of the lower surface 211b.

The first lower metal part 232A partially overlaps with the metal film 261 in a top view. More specifically, the first lower metal part 232A partially overlaps with the recessed portion of the metal film 261 in a top view. The first lower metal part 232A does not overlap with the recess 217 in a top view. The first lower metal part 232A does not overlap with the projecting portion of the metal film 261 and the metal part 231 in a top view.

The second lower metal part 232B partially overlaps with the metal part 231 and the metal film 261 in a top view. More specifically, the second lower metal part 232B partially overlaps with the recessed portion of the metal part 231 and the projecting portion of the metal film 261 in a top view. In the illustrated example, the second lower metal part 232B does not overlap with the recess 217 in a top view. The second lower metal part 232B may partially overlap with the recess 217 in a top view.

The third lower metal part 232C partially overlaps with the metal part 231 in a top view. More specifically, the third lower metal part 232C partially overlaps with the projecting portion of the metal part 231 in a top view. The third lower metal part 232C partially overlaps with the recess 217 in a top view. The third lower metal part 232C does not overlap with the metal film 261 in a top view.

As illustrated in FIG. 5 and FIG. 6, the base 211 may be provided with a first via wiring 233V. The first via wiring 233V is connected to the metal film 261 and is provided in a through hole 233 penetrating the base 211. In a top view, the first via wiring 233V is connected to the metal film 261 at a position where the recessed portion of the metal film 261 is located. Further, the base 211 may be provided with a second via wiring 234V. The second via wiring 234V is connected to the metal part 231 and is provided in a through hole 234 penetrating the base 211. In a top view, the second via wiring 234V is connected to the metal part 231 at a position where the recessed portion of the metal part 231 is located. The through hole 233 and the through hole 234 penetrate from the upper surface 211a to the lower surface 211b of the base 211. In the illustrated example, two first via wirings 233V and two second via wirings 234V are provided; however, one first via wiring 233V and one second via wiring 234V may be provided, or three or more first via wirings 233V and three or more second via wirings 234V may be provided. Each of the through holes 233 and 234 has, for example, a circular shape, an elliptical shape, a rectangular shape, or the like in a top view.

The first via wiring 233V is connected to the first lower metal part 232A. The metal film 261 is electrically connected to the first lower metal part 232A via the first via wiring 233V. The second via wiring 234V is connected to the second lower metal part 232B. The metal part 231 is electrically connected to the second lower metal part 232B via the second via wiring 234V. No via wiring may be connected to the third lower metal part 232C. The third lower metal part 232C may be electrically floated.

As illustrated in FIG. 6, a metal film 262 having a rectangular frame shape and surrounding the metal film 261 and the metal part 231 in a top view may be provided on the base 211. Further, in a top view, a metal adhesive 263 is applied to the upper surface of the metal film 262 to bond the lateral walls 213, which will be described later. Examples of the metal adhesive 263 include AuSn. The metal film 262 is spaced apart from the metal film 261 and the metal part 231 in a top view. In FIG. 6, the metal adhesive 263 is illustrated in a dot pattern for convenience.

Examples of the metal films 261 and 262 include Ni/Au (a metal film in which Ni and Au are stacked in this order) and Ti/Pt/Au (a metal film in which Ti, Pt, and Au are stacked in this order). The thickness of the metal film 262 can be the same as or similar to the thickness of the metal film 261.

### (Lateral Walls 213 and Cover 214)

One or more lateral walls 213 meet the base 211 and extend upward from the upper surface 211a. Each of the lateral walls 213 has an upper surface 213a, a lower surface 213b, inner lateral surfaces, and outer lateral surfaces. The lateral walls 213 have a rectangular frame shape in a top view. The inner lateral surface and the outer lateral surface of each of the lateral walls 213 meet the upper surface 211a of the base 211.

The cover 214 is disposed on the lateral walls 213. The cover 214 has an upper surface 214a and a lower surface 214b. The cover 214 has, for example, a flat plate shape. The upper surface 214a and the lower surface 214b may or may not be parallel to each other. Further, the cover 214 has one or more lateral surfaces connected to the upper surface 214a and the lower surface 214b. The one or more lateral surfaces are connected to the outer edge of the upper surface 214a and the outer edge of the lower surface 214b. The cover 214 is, for example, a rectangular parallelepiped or a cube. In this case, each of the upper surface 214a and the lower surface 214b of the cover 214 has a rectangular shape, and the cover 214 has four lateral surfaces each having a rectangular shape. The cover 214 is not necessarily a rectangular parallelepiped or a cube. That is, the shape of the cover 214 is not limited to a rectangular shape in a top view. The cover 214 can have any shape such as a circular shape, an elliptical shape, or a polygonal shape in a top view.

The lower surface 213b of each of the lateral walls 213 is bonded to the upper surface 211a of the base 211. In addition, the upper surface 213a of each of the lateral walls 213 is bonded to the lower surface 214b of the cover 214. For example, a metal adhesive may be used to bond the lateral walls 213 to the base 211 and to the cover 214. Examples of the metal adhesive include AuSn and a metal paste. A resin adhesive may be used to bond the lateral walls 213 to the base 211 and to the cover 214.

The lateral walls 213 can be formed of, for example, silicon as the main material. Other examples of the main material of the lateral walls 213 include sapphire, quartz, glass, and ceramic. As the ceramic, aluminum nitride, silicon nitride, aluminum oxide, or silicon carbide can be used. The cover 214 can be formed of, for example, sapphire, quartz, silicon carbide, glass, silicon, or the like. The cover 214 has a light transmitting region that transmits light having a predetermined wavelength. The entire cover 214 may be a light transmitting region. The lateral walls 213 and the cover 214 may be integrally formed of the same main material.

### (Light Emitting Element 220)

The light emitting element 220 is, for example, a semiconductor laser element. The light emitting element 220 is not limited to a semiconductor laser element, and may be, for example, a light emitting diode (LED), an organic light emitting diode (OLED), or the like. In the illustrated light emitting device 200, a semiconductor laser element is employed as the light emitting element 220.

The outer shape of the light emitting element 220 is, for example, a rectangle in a top view. Further, a lateral surface on one short side of two short sides of this rectangle serves as an emission end surface 220a of the light emitting element 220 from which light is emitted. The upper surface and the lower surface of the light emitting element 220 are larger in area than the emission end surface 220a. A metal film may be provided on the upper surface of the light emitting element 220. For example, wiring or the like for electrical conduction to other members is provided on the metal film. The metal film is not necessarily provided on the upper surface of the light emitting element 220.

An example in which the light emitting element 220 is a semiconductor laser element will be described. Light (laser light) emitted from the light emitting element 220 spreads and forms an elliptical far field pattern (hereinafter referred to as “FFP”) on a plane parallel to the emission end surface. The FFP indicates the shape and the light intensity distribution of the emitted light at a position away from the emission end surface.

In the elliptical light emitted from the light emitting element 220, the direction passing through the major axis of the elliptical shape is defined as the fast axis direction of the FFP, and the direction passing through the minor axis of the elliptical shape is defined as the slow axis direction of the FFP. The fast axis direction of the FFP in the light emitting element 220 can correspond to the stacking direction in which a plurality of semiconductor layers including an active layer of the light emitting element 220 are stacked.

Further, light having an intensity of 1/e² or more of the peak intensity within the light intensity distribution of the FFP of the light emitting element 220 is referred to as the main portion of light. An angle corresponding to an intensity of 1/e² in the light intensity distribution is referred to as an angle of divergence. The angle of divergence in the fast-axis direction of the FFP is larger than the angle of divergence in the slow-axis direction of the FFP.

Further, light passing through the center of the elliptical shape of the FFP, in other words, light with the peak intensity in the light intensity distribution of the FFP, is referred to as light traveling along the optical axis or light passing through the optical axis. An optical path of light traveling along the center of the elliptical shape of the FFP is referred to as the optical axis of the light.

A light emitting element that emits visible light may be used as the light emitting element 220. Examples of the light emitting element that emits visible light include light emitting elements that emit blue light, green light, or red light. The light emitting elements that emit blue light, green light, or red light refer to light emitting elements in which emission peak wavelengths of emitted light are in a range of 405 nm to 494 nm, in a range of 495 nm to 570 nm, or in a range of 605 nm to 750 nm, respectively. Examples of the light emitting element 220 that emits blue light or green light include a semiconductor laser element including a nitride semiconductor. As the nitride semiconductor, for example, GaN, InGaN, or AlGaN can be used. Examples of the light emitting element 220 that emits red light include a semiconductor laser element including an InAlGaP-based semiconductor, a GaInP-based semiconductor, a GaAs-based semiconductor, or an AlGaAs-based semiconductor.

The emission peak of light emitted from the light emitting element 220 is not necessarily limited to the above. For example, light emitted from the light emitting element 220 may be visible light of any color other than the above-described colors. Further, a light emitting element that emits ultraviolet light, infrared light, or the like other than visible light may be used.

### (Reflective Member 240)

As illustrated in FIG. 7, the reflective member 240 has a reflective surface 240a that reflects light upward, a lower surface 240b, an inclined surface 240c, a first lateral surface 240d, a second lateral surface 240e, a third lateral surface 240f, a fourth lateral surface 240g, and a fifth lateral surface 240h. In the illustrated light emitting device 200, the surfaces of the reflective member 240 are flat surfaces.

In the light emitting device 200 illustrated in FIG. 1 through FIG. 6, the reflective surface 240a has a rectangular shape. The reflective surface 240a is inclined with respect to the lower surface 240b. For example, when the lower surface 240b serves as a placement surface (mounting surface) on another member, at least a portion of the reflective member 240 is located lower than the lowest point of the lower surface 240b in a direction normal to the lower surface 240b. With this configuration, for example, in the light emitting device 200, the lower surface 240b of the reflective member 240 can be bonded to the upper surface 211a of the base 211, and a portion of the reflective surface 240a can be disposed in the recess 217 in whole or part. The inclination angle of the reflective surface 240a with respect to the lower surface 240b is, for example, 45 degrees. When a specific inclination angle is described, a tolerance of ±5 degrees from the specific angle is allowed for products in consideration of manufacturing accuracy. The same applies to parallel and perpendicular components.

The reflective surface 240a is connected to the first lateral surface 240d, the second lateral surface 240e, the third lateral surface 240f, and the fourth lateral surface 240g. The reflective surface 240a is not connected to the lower surface 240b, the inclined surface 240c, and the fifth lateral surface 240h.

The inclined surface 240c is inclined with respect to the lower surface 240b. The inclined surface 240c is located opposite the reflective surface 240a. The inclination angle of the inclined surface 240c with respect to the lower surface 240b is, for example, 45 degrees, and may be the same as the inclination angle of the reflective surface 240a. In the illustrated example, the inclined surface 240c is parallel to the reflective surface 240a. The inclined surface 240c is connected to the lower surface 240b. In addition, the inclined surface 240c is connected to the first lateral surface 240d, the second lateral surface 240e, and the third lateral surface 240f. The inclined surface 240c is not connected to the reflective surface 240a, the fourth lateral surface 240g, and the fifth lateral surface 240h. The inclined surface 240c has, for example, a rectangular shape. The area of the inclined surface 240c is smaller than the area of the reflective surface 240a. In addition, the area of the inclined surface 240c is preferably smaller than the area of the lower surface 240b. The area of the inclined surface 240c is preferably less than one-half of the area of the lower surface 240b. Accordingly, the area of the lower surface 240b bonded to the base 211 can be sufficiently secured.

The first lateral surface 240d and the second lateral surface 240e are opposite to each other with the reflective surface 240a interposed therebetween in the short side direction of the reflective surface 240a. Each of the first lateral surface 240d and the second lateral surface 240e has six sides, and the six sides are respectively connected to six surfaces. In the illustrated example, the first lateral surface 240d and the second lateral surface 240e are perpendicular to the lower surface 240b. In the illustrated example, the first lateral surface 240d and the second lateral surface 240e are parallel to each other. In the illustrated example, the first lateral surface 240d and the second lateral surface 240e are parallel to the XZ plane and have the same shape. In the illustrated example, the area of the first lateral surface 240d is the same as the area of the second lateral surface 240e. The area and the shape of each of the first lateral surface 240d and the second lateral surface 240e are not limited thereto.

The third lateral surface 240f and the fourth lateral surface 240g are inclined with respect to the lower surface 240b. The third lateral surface 240f and the fourth lateral surface 240g are opposite to each other with the reflective surface 240a interposed therebetween in the long side direction of the reflective surface 240a. The third lateral surface 240f is connected to the reflective surface 240a, the inclined surface 240c, the first lateral surface 240d, and the second lateral surface 240e. The fourth lateral surface 240g is connected to the reflective surface 240a, the first lateral surface 240d, the second lateral surface 240e, and the fifth lateral surface 240h. In the illustrated example, the third lateral surface 240f and the fourth lateral surface 240g are parallel to each other. In the illustrated example, the third lateral surface 240f and the fourth lateral surface 240g have, for example, a rectangular shape, and may have the same shape. The area of the third lateral surface 240f is smaller than the area of the fourth lateral surface 240g.

The fifth lateral surface 240h is inclined with respect to the lower surface 240b. The fifth lateral surface 240h is located opposite the reflective surface 240a. The fifth lateral surface 240h is connected to the lower surface 240b, the first lateral surface 240d, the second lateral surface 240e, and the fourth lateral surface 240g. In the illustrated example, the fifth lateral surface 240h and the reflective surface 240a are parallel to each other. In addition, in the illustrated example, the fifth lateral surface 240h, the inclined surface 240c, and the reflective surface 240a are parallel to one another. The area of the fifth lateral surface 240h is smaller than the area of the reflective surface 240a. The fifth lateral surface 240h has, for example, a rectangular shape.

The reflective surface 240a may be a curved surface, or may be a combination of a flat surface and a curved surface. Further, the reflective surface 240a does not necessarily have a rectangular shape as long as the reflective surface 240a can reflect incident light in a desired direction. Similarly, the other surfaces of the reflective member 240 do not necessarily have the above-described shapes.

Glass, metal, or the like can be used as the main material forming the outer shape of the reflective member 240. The main material is preferably a heat-resistant material, and, for example, glass such as quartz or BK7 (borosilicate glass), metal such as aluminum, or silicon can be used. Further, the reflective surface 240a can be formed by using, for example, metal such as Ag or Al, or a dielectric multilayer film such as Ta₂O₅/SiO₂, TiO₂/SiO₂, or Nb₂O₅/SiO₂.

### (Protective Element 250)

The protective element 250 is a component for protecting specific elements such as semiconductor laser elements. For example, the protective element 250 is a component for preventing specific elements such as semiconductor laser elements from being broken by an excessive current flowing therethrough. For example, a Zener diode formed of Si can be used as the protective element 250. Further, for example, the protective element 250 may be a component for measuring the temperature to ensure that specific elements do not fail due to the temperature environment. A thermistor can be used as such a temperature measuring element. The temperature measuring element may be disposed near the emission end surface of the light emitting element 220.

### (Wiring 270)

The wiring 270 is composed of a conductor having a linear shape with both ends serving as bonding portions. In other words, the wiring 270 has, at both ends of the linear-shaped portion, bonding portions bonded to other components. The wiring 270 is used for electrical connection between two components. As the wiring 270, for example, a metal wire can be used. Examples of the metal include gold, aluminum, silver, copper, and tungsten.

### (Manufacturing Method of Reflective Member 240)

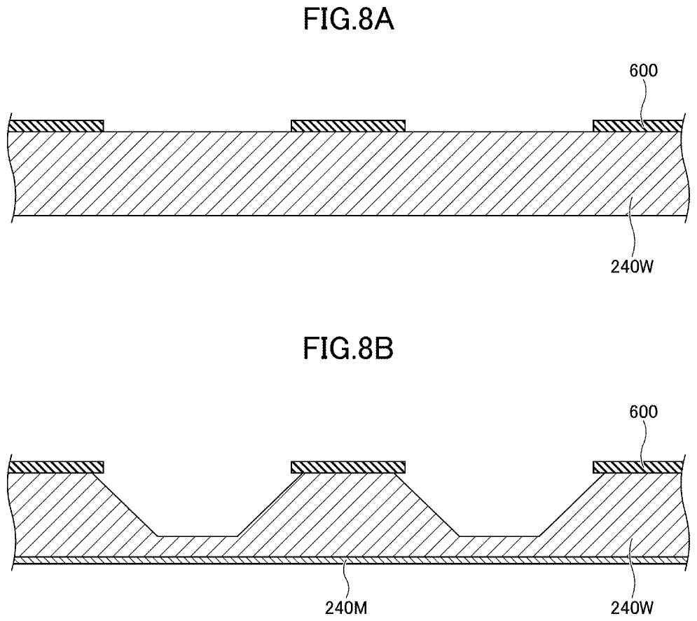

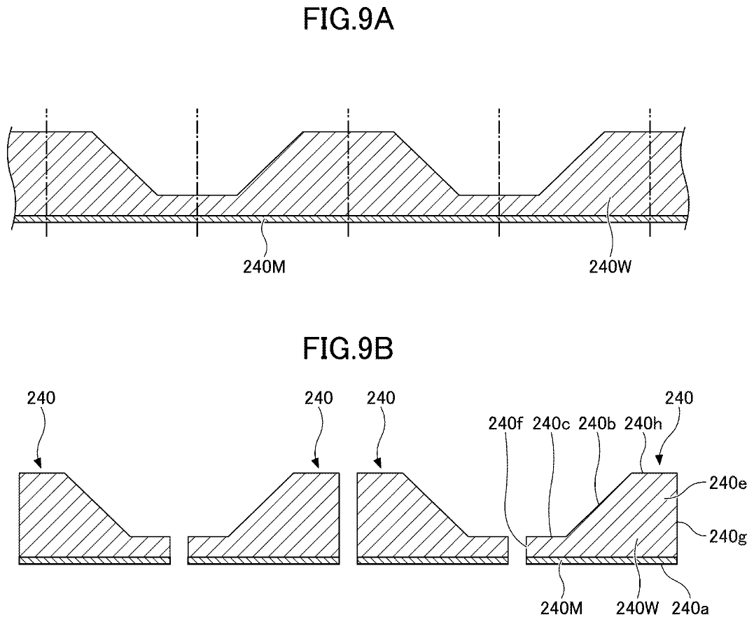

A manufacturing method of the reflective member 240 according to the present embodiment will be described with reference to FIG. 8A through FIG. 9B. FIG. 8A through FIG. 9B are cross-sectional views illustrating the manufacturing method of the reflective member 240 according to the present embodiment. First, as illustrated in FIG. 8A, a silicon wafer 240W having a constant thickness is provided. A mask 600 having openings partially exposing the upper surface of the silicon wafer 240W is formed on the silicon wafer 240W. The mask 600 is, for example, a silicon oxide film formed by thermally oxidizing the surface of the silicon wafer 240W. The openings of the mask 600 can be formed, for example, by removing portions of the silicon oxide film by reactive ion etching or the like. In the following, in the silicon wafer 240W illustrated in FIG. 8A through FIG. 9B, a surface on which the mask 600 is formed is described as an upper surface and a surface opposite the upper surface is described as a lower surface.

Subsequently, as illustrated in FIG. 8B, portions of the silicon wafer 240W exposed through the openings of the mask 600 are removed by etching. After the etching, a plurality of recesses is formed in the upper surface of the silicon wafer 240W. Each of the recesses is defined by two inclined surfaces and a bottom surface. The inclined surfaces are surfaces that are connected to the upper surface and are inclined with respect to the upper surface. The inclination angle of each of the inclined surfaces is, for example, 45 degrees. The bottom surface is a surface that is connected to the two inclined surfaces and is parallel to, for example, the upper surface and the lower surface. After the silicon wafer 240W is divided as will be described later, the bottom surface serves as the inclined surface 240c of the reflective member 240, and one of the inclined surfaces serves as the lower surface 240b of the reflective member 240.

The length from the upper surface to the bottom surface is greater than the length from the bottom surface to the lower surface in a direction normal to the upper surface. More preferably, the length from the upper surface to the bottom surface is twice or more the length from the bottom surface to the lower surface. This relationship between the lengths allows the area of the lower surface 240b to be sufficiently secured in the reflective member 240 after the silicon wafer 240W is divided. The etching is performed such that the area of the bottom surface is substantially the same as the area of the upper surface. By making the area of the bottom surface substantially the same as the area of the upper surface, the size of the inclined surface 240c of the reflective member 240 can be sufficiently secured after the silicon wafer 240W is divided.

Subsequently, a reflective film 240M is formed on the lower surface of the silicon wafer 240W. The reflective film 240M can be formed by using, for example, metal such as Ag or Al, or a dielectric multilayer film such as Ta₂O₅/SiO₂, TiO₂/SiO₂, or Nb₂O₅/SiO₂. The reflective film 240M can be formed by, for example, sputtering. The lower surface on which the reflective film 240M is formed serves as the reflective surface 240a of the reflective member 240 after the silicon wafer 240W is divided.

Subsequently, the mask 600 is removed by reactive ion etching, wet etching, dry etching, or the like. Then, by cutting the silicon wafer 240W at positions indicated by dash-dot lines in FIG. 9A, the silicon wafer 240W is divided as illustrated in FIG. 9B. As a result, a plurality of reflective members 240 are obtained. The silicon wafer 240W can be cut by using, for example, a blade, a laser, or the like.

Anisotropic etching using an alkaline aqueous solution such as an aqueous potassium hydroxide (KOH) solution, a tetramethylammonium hydroxide (TMAH) solution, ethylenediamine pyrocatechol water (EDP) can be applied to the etching of the silicon wafer 240W in FIG. 8B. In this case, if each of the upper surface and the lower surface of the silicon wafer 240W is a (100) plane, a shape whose inclined surfaces are each a flat (111) plane is formed, and the angle formed by the (100) plane and the (111) plane is approximately 54.7°. That is, in FIG. 9B, the inclination angle of the reflective surface 240a with respect to the lower surface 240b is approximately 54.7°. If the upper surface and the lower surface of the silicon wafer 240W has an off-angle of 9.7° with respect to the (100) plane, inclined surfaces of approximately 45° with respect to the upper surface and the lower surface can be formed. That is, in FIG. 9B, the inclination angle of the reflective surface 240a with respect to the lower surface 240b is approximately 45°.

In addition, anisotropic etching using an etching solution obtained by adding isopropyl alcohol to an aqueous potassium hydroxide (KOH) solution can be applied to the etching of the silicon wafer 240W. In this case, if each of the upper surface and the lower surface of the silicon wafer 240W is a (100) plane, a shape whose inclined surfaces are each a flat (110) plane is formed, and the angle formed by the (100) plane and the (110) plane is approximately 45°. That is, in FIG. 9B, the inclination angle of the reflective surface 240a with respect to the lower surface 240b is approximately 45°.

The manufacturing method of the reflective member 240 according to the present embodiment has been described above; however, the manufacturing method of the reflective member 240 is not limited thereto.

### (Light Emitting Device 200)

Subsequently, the light emitting device 200 will be described.

The light emitting element 220 is disposed on the upper surface 211a of the base 211. More specifically, the light emitting element 220 is disposed on the upper surface 211a of the base 211 with the metal part 231 being interposed therebetween. The light emitting element 220 is bonded to an upper surface 231a of the metal part 231. Similarly, the protective element 250 is disposed on the upper surface 211a of the base 211 with the metal part 231 being interposed therebetween. For example, the light emitting element 220 includes a metal film on the lower surface thereof, and the metal film of the light emitting element 220 is bonded to a metal film provided on the upper surface 231a of the metal part 231. These metal films are bonded to each other via a metal adhesive, for example. Examples of the metal adhesive used to bond these metal films include AuSn. The thickness of the metal film provided on the lower surface of the light emitting element 220 and the thickness of the metal film provided on the upper surface 231a of the metal part 231 can be the same as or similar to the thickness of the metal film 261.

In the illustrated example, in a top view as seen in a direction perpendicular to the upper surface 211a, the light emitting element 220 is laterally surrounded by the lateral walls 213. In the following, as used in the description of the light emitting device, the term “top view” refers to a top view as seen in a direction perpendicular to the upper surface 211a of the base 211, unless otherwise noted. The light emitting element 220 emits light laterally from the emission end surface 220a. In the illustrated example, the optical axis of the light emitted laterally from the emission end surface 220a is parallel to the first direction X. The light emitted from the light emitting element 220 is, for example, visible light such as blue light, green light, or red light. The light emitted from the light emitting element 220 is not limited to visible light. For example, as the light emitting element 220, a light emitting element that emits ultraviolet light or infrared light may be used. Further, in the illustrated example, the light emitting element 220 is a semiconductor laser element.

The light emitting element 220 is disposed such that the emission end surface 220a faces the same direction as the lateral surface 231c of the metal part 231. The emission end surface 220a of the light emitting element 220 is perpendicular to the first direction X. Further, the emission end surface 220a of the light emitting element 220 can be parallel to or perpendicular to, for example, one inner lateral surface or one outer lateral surface of the lateral walls 213. In a top view, the light emitting element 220 does not overlap with the recess 217. Further, the entire light emitting element 220 is preferably disposed on the upper surface 231a of the metal part 231. Accordingly, heat dissipation of the light emitting element 220 can be improved.

The light emitting element 220 is disposed on the upper surface 231a of the projecting portion of the metal part 231 in a top view. The protective element 250 is disposed across the projecting portion and the recessed portion of the metal part 231. More specifically, the light emitting element 220 and the protective element 250 are arranged side by side in the second direction Y on the upper surface of the metal part 231. Further, in a top view, the light emitting element 220 overlaps with a virtual plane that overlaps with the lateral surface 231d and that is parallel to the lateral surface 231d. The protective element 250 does not overlaps with the above-described virtual plane. In a top view, the light emitting element 220 does not overlap with the metal film 261. In a top view, the light emitting element 220 overlaps with a virtual line extending from the side 261d. The protective element 250 does not overlaps with the above-described virtual line.

The reflective member 240 is disposed on the upper surface 211a of the base 211. More specifically, the reflective member 240 is disposed on the upper surface 211a on which the light emitting element 220 is disposed. That is, the light emitting element 220 and the reflective member 240 are arranged in the same plane on the upper surface 211a of the base 211. By arranging the light emitting element 220 and the reflective member 240 in the same plane, the light emitting element 220 and the reflective member 240 can be arranged with high accuracy. With this arrangement, light emitted from the light emitting element 220 can be accurately reflected by the reflective surface 240a with its optical axis being directed in the direction perpendicular to the upper surface 211a. Further, the reflective member 240 is disposed to face the light emitting element 220 with the recess 217 interposed between the reflective member 240 and the light emitting element 220. The reflective surface 240a of the reflective member 240 faces the emission end surface 220a of the light emitting element 220. The reflective surface 240a upwardly reflects light emitted from the emission end surface 220a of the light emitting element 220.

The lower surface 240b of the reflective member 240 is disposed on the upper surface 211a of the base 211. The reflective member 240 can be disposed on the metal film 261 provided on the upper surface 211a such that the metal film 261 is provided directly under the reflective member 240. The lower surface 240b of the reflective member 240 is located lower than the upper surface 231a of the metal part 231.

For example, the reflective member 240 includes a metal film on the lower surface 240b, and the metal film of the reflective member 240 and the metal film 261 can be bonded to each other via a metal adhesive, for example. Examples of the metal adhesive used to bond the metal films include AuSn. The thickness of the metal film provided on the lower surface 240b of the reflective member 240 can be the same as or similar to the thickness of the metal film 261. Further, the lower surface 240b of the reflective member 240 is disposed on the recessed portion of the metal film 261 in a top view. The reflective member 240 does not overlap with the projecting portion of the metal film 261 in a top view.

At least a portion of the reflective surface 240a overlaps with the recess 217 in a top view. Further, at least a portion of the lower surface 240b overlaps with the recess 217 in a top view. In the illustrated example, in a top view, a portion of the reflective surface 240a is located inside the recess 217 and the other portion is located outside the recess 217. The length of the reflective surface 240a is greater than the length of the recess 217 in the first direction X. The length of the reflective surface 240a is smaller than the length of the recess 217 in the second direction Y.

A point on the most positive side in the first direction X of the reflective surface 240a is located closer to the fourth lateral surface 240g of the reflective member 240 than the edge 217c of the recess 217 is (located on the positive side in the first direction X relative to the edge 217c) in a top view. A point on the most negative side in the first direction X of the reflective surface 240a is located closer to the fourth lateral surface 240g of the reflective member 240 than the edge 217d of the recess 217 is (located on the positive side in the first direction X relative to the edge 217d) in a top view. In addition, a point on the most positive side in the first direction X of the inclined surface 240c is located closer to the light emitting element 220 than the edge 217c of the recess 217 is (located on the negative side in the first direction X relative to the edge 217c) in a top view. A point on the most negative side in the first direction X of the inclined surface 240c is located closer to the fourth lateral surface 240g of the reflective member 240 than the edge 217d of the recess 217 is (located on the positive side in the first direction X relative to the edge 217d) in a top view.

The lower end of the reflective surface 240a is located lower than the upper surface 211a of the base 211 and higher than the bottom surface 217b of the recess 217 in a direction normal to the upper surface 211a. Further, the inclined surface 240c is located in the recess 217 in whole or part. Specifically, the lower end of the inclined surface 240c is located in the recess 217 in whole or part, and is located lower than the upper surface 211a of the base 211 and higher than the bottom surface 217b of the recess 217. That is, the lower end of the reflective member 240 is spaced apart from any of the surfaces defining the recess 217 in the third direction Z. There is a space between the bottom surface 217b of the recess 217 and the lower end of the reflective member 240. There is a space on a straight line connecting the bottom surface 217b and the lower end of the reflective member 240.

The area of a portion of the reflective surface 240a located higher than (located on the positive side in the third direction Z relative to) the upper surface 211a is larger than the area of a portion of the reflective surface 240a located lower than the upper surface 211a. In other words, the area of a portion of the reflective surface 240a located higher than the recess 217 is larger than the area of a portion of the reflective surface 240a located in the recess 217. Conversely, the area of a portion of the inclined surface 240c located higher than the upper surface 211a is smaller than the area of a portion of the inclined surface 240c located lower than the upper surface 211a. In the illustrated example, the side of the inclined surface 240c meeting the lower surface 240b is at the same height as the upper surface 211a, and all the other portions of the inclined surface 240c are located lower than the upper surface 211a.

As described, in the light emitting device 200, a portion of the reflective surface 240a of the reflective member 240 is disposed in the recess 217. With this structure, the bottom surface 217b of the recess 217 does not have to be strictly parallel to the upper surface 211a, unlike a case where the reflective member 240 is disposed on the bottom surface 217b of the recess 217. Therefore, processing in forming the recess 217 can be facilitated. In addition, because the size of the recess 217 can be reduced, a decrease in the strength of the base 211 can be reduced.

Further, the lower end of the reflective member 240 is located higher than the bottom surface 217b of the recess 217. Therefore, the surface roughness of the bottom surface 217b of the recess 217 does not affect the arrangement accuracy of the reflective member 240, thus eliminating the need to flatten the bottom surface 217b of the recess 217. In addition, when the lower end of the reflective member 240 is spaced apart from any of the surfaces defining the recess 217, the surface accuracy of any of the surfaces defining the recess 217 does not affect the arrangement accuracy of the reflective member 240.

The inclination angle of a lateral surface, of the one or more lateral surfaces of the recess 217, connected to the lower surface 240b of the reflective member 240 with respect to the bottom surface 217b is larger than the inclination angle of the reflective surface 240a with respect to the bottom surface 217b. That is, the inclination angle of the lateral surface including the edge 217c is larger than the inclination angle of the reflective surface 240a. Further, the larger the inclination angles of the lateral surfaces of the recess 217 with respect to the bottom surface 217b, the smaller the recess 217 can be in the first direction X and the second direction Y. As a result, the size of the light emitting device 200 in the first direction X and the second direction Y can be reduced.

The area of the bottom surface 217b of the recess 217 is preferably smaller than the area of the lower surface 240b of the reflective member 240. Further, the length of the recess 217 is preferably less than the length of the lower surface 240b of the reflective member 240 in a direction perpendicular to the emission end surface 220a. Further, the depth of the recess 217 is preferably one-half or less of the thickness of the base 211. With this structure, the size of the recess 217 can be reduced, and thus, processing in forming the recess 217 can be facilitated. In addition, because the size of the recess 217 can be reduced, a decrease in the strength of the base 211 can be reduced.

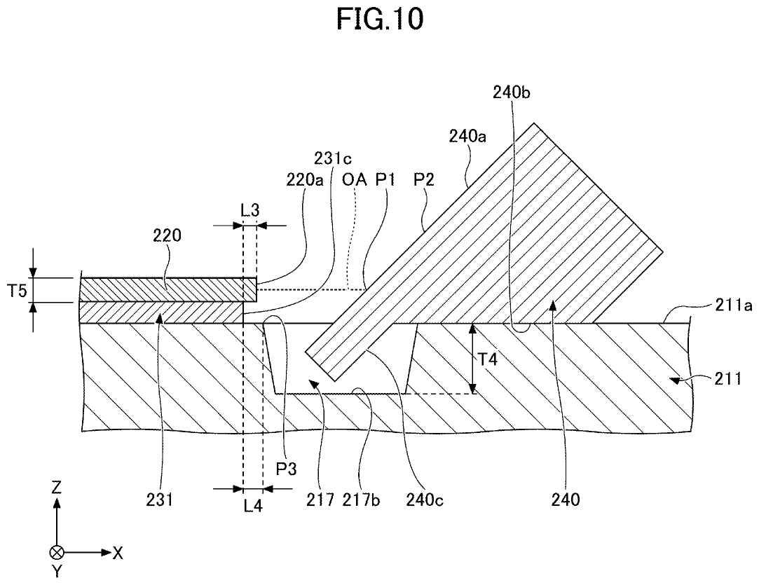

FIG. 10 is an enlarged cross-sectional view of the light emitting element 220, the reflective member 240, and their surroundings in the light emitting device 200 illustrated in FIG. 4. As illustrated in FIG. 10, in the light emitting device 200, a portion of the reflective surface 240a of the reflective member 240 is disposed in the recess 217. Therefore, of the main portion of light emitted from the emission end surface 220a, a portion of light directed downward with respect to an optical axis OA reaches a portion of the reflective surface 240a located in the recess 217 and is reflected upward. Therefore, in the light emitting device 200, there is no need to use a submount to dispose the light emitting element 220. As a result, the number of members of the light emitting device 200 can be reduced. Consequently, the size of the light emitting device 200 can be reduced.

Further, as illustrated in FIG. 10, a point P1 at which the optical axis OA of the light emitted from the light emitting element 220 meets the reflective surface 240a is located lower than a center point P2 of the reflective surface 240a in the third direction Z. In addition, the center point P2 of the reflective surface 240a is located higher than the upper surface 211a. Because the center point P2 of the reflective surface 240a is located higher than the upper surface 211a, the area of a portion of the reflective surface located in the recess 217 can be minimized. Accordingly, the size of the recess 217 can be reduced, and thus, processing in forming the recess 217 can be easily performed. In addition, because the size of the recess 217 can be reduced, a decrease in the strength of the base 211 can be reduced.

A length T4 from the bottom surface 217b of the recess 217 to the upper surface 211a is preferably six times or less a thickness T5 of the light emitting element 220 in the third direction Z. Because the depth of the recess 217 is small, processing in forming the recess 217 can be easily performed. In addition, having the recess 217 with a small depth can suppress a decrease in the strength of the base 211.

Of the main portion of the light emitted from the emission end surface 220a, light directed downward with respect to the optical axis OA reaches a portion of the reflective surface 240a located lower than the center point P2 in the third direction Z. The light directed downward with respect to the optical axis OA may reach a portion of the reflective surface 240a located in the recess 217. The light directed downward with respect to the optical axis OA does not reach a portion of the reflective surface 240a located higher than the center point P2.

As illustrated in FIG. 10, the lateral surface 231c of the metal part 231 does not preferably overlap with the recess 217 in the first direction X in a top view. Further, a distance L3 between the lateral surface 231c of the metal part 231 and the emission end surface 220a in the direction perpendicular to the emission end surface 220a is, for example, 50 μm or less. The emission end surface 220a can protrude further toward the reflective member 240 than the lateral surface 231c. In this case, the light emitted from the emission end surface 220a is less likely to strike the upper surface of the metal part 231. A distance L4 between the lateral surface 231c of the metal part 231 and a point P3 of the recess 217 closest to the light emitting element 220, in the direction perpendicular to the emission end surface 220a is, for example, 0 μm or more and 150 μm or less.

In the illustrated example, the metal part 231 and the metal film 261 are provided so as to surround the recess 217. More specifically, the recessed portion of the metal film 261 is located on the positive side in the first direction X relative to the edge 217c of the recess 217. The projecting portion of the metal film 261 is located on the positive side in the second direction Y relative to the edge 217e. The projecting portion of the metal part 231 is located on the negative side in the first direction X relative to the edge 217d. The metal part 231 and metal film 261 are not provided on the negative side in the second direction Y relative to the edge 217f. Further, the metal part 231 and the metal film 261 are longer than the recess 217 in the first direction X. As described, the metal part 231 and the metal film 261 are provided so as not to overlap with the recess 217. Further, the metal part 231 and the metal film 261 surround the recess 217 such that the projecting portion of the metal part 231 is in proximity to the projecting portion of the metal film 261. By providing the metal part 231 and the metal film 261 as described above, the wiring 270, which will be described later, can be easily connected.

In the example illustrated in FIG. 3, a plurality of wirings 270 are bonded to the light emitting element 220. One end of each of the wirings 270 is bonded to the upper surface of the light emitting element 220, and the other end of each of the wirings 270 is bonded to the projecting portion on the light emitting element 220 side of the metal film 261 (on the negative side in the first direction X) relative to the side 261c. Accordingly, the lengths of the wirings 270 connecting the metal film 261 and the light emitting element 220 can be reduced.

Further, the arrangement of members will be described with reference to FIG. 6. A virtual line passing through the recess 217 and parallel to the second direction Y passes through the metal film 261 in a top view. More specifically, this virtual line passes through the projecting portion of the metal film 261. This virtual line does not pass through the recessed portion of the metal film 261. Further, a virtual line passing through the recess 217 and parallel to the first direction X passes through the light emitting element 220 and the reflective member 240 in a top view.

At least one of the wirings 270 connected to the light emitting element 220 overlap with the recess 217 in a top view. Specifically, among the plurality of wirings 270 connected to the upper surface of the light emitting element 220, a wiring 270 located closest to the reflective member 240 is connected to the projecting portion of the metal film 261 at a position closest to the reflective member 240. This wiring 270 overlaps with the recess 217 in a top view. The wirings other than this wiring do not overlap with the recess 217 in a top view.

In the example illustrated in FIG. 3, one of the wirings 270 is bonded to the protective element 250. One end of this wiring 270 is bonded to the protective element 250, and the other end of this wiring 270 is bonded to the projecting portion on the light emitting element 220 side of the metal film 261 relative to the side 261c in the first direction X. The wiring 270 connected to the protective element 250 is bonded to the projecting portion on the protective element 250 side of the metal film 261 relative to the wirings connected to the light emitting element 220.

For the electrical connection between the light emitting element 220 and an external power source, the first lower metal part 232A and the second lower metal part 232B provided on the lower surface 211b of the base 211 can be used, for example.

The lower surfaces 213b of the lateral walls 213 is bonded to the outer edge of the upper surface 211a of the base 211. For example, a metal film provided on the lower surface 213b of at least one of the lateral walls 213 is bonded and fixed to the metal film 262 provided on the upper surface 211a of the base 211 via the metal adhesive 263. The upper surface 213a at least one of the lateral walls 213 is bonded to the outer edge of the lower surface 214b of the cover 214. For example, a metal film provided on the upper surface 213a of at least one of the lateral walls 213 is bonded and fixed to a metal film provided on the lower surface 214b of the cover 214 via a metal adhesive. By bonding the lateral walls 213 to the cover 214 and the base 211, a sealed space surrounded by the base 211, the lateral walls 213, and the cover 214 is formed. The sealed space may be formed to be airtight. The airtightly sealed space can suppress collection of dust such as organic substances on the emission end surface 220a of the light emitting element 220.

The cover 214 has the light transmitting region through which light reflected upward with respect to the reflective member 240 is transmitted and emitted to the outside. That is, light reflected upward with respect to the reflective member 240 is transmitted through the light transmitting region of the cover 214 and is emitted from the upper surface 214a to the outside of the light emitting device 200. In the light transmitting region, the lower surface 214b of the cover 214 serves as a light incident surface on which light reflected by the reflective surface 240a of the reflective member 240 is incident. The upper surface 214a of the cover 214 serves as a light emission surface from which the light incident on the light incident surface exits the outside of the light emitting device 200. The entire cover 214 may be the light transmitting region. The light transmitting region of the cover 214 transmits 70% or more of light reflected upward with respect to the reflective member 240. As illustrated in FIG. 4, the difference between a length L1 from the lower surface 214b (serving as the light incident surface) of the cover 214 to the upper surface 211a of the base 211 and a length L2 from the upper end to the lower end of the reflective surface 240a in the third direction Z is, for example, 200 μm or less. With this configuration, the size of the light emitting device 200 in the third direction Z can be reduced.

The length of the light emitting device 200 in the first direction X is, for example, 2,500 μm or more and 4,000 μm or less. The length of the light emitting device 200 in the second direction Y is, for example, 1,800 μm or more and 2,500 μm or less. The length of the light emitting device 200 in the third direction Z is, for example, 1,500 μm or more and 2,100 μm or less. The light emitting device 200 according to the present disclosure is a light emitting device suitable for size reduction. Further, the light emitting device 200 can be designed to not include a heat dissipation member such as a submount in addition to the metal parts and the base. Accordingly, the number of members of the light emitting device 200 can be reduced. As a result, the productivity of manufacturing the light emitting device 200 can be improved.

### Second Embodiment

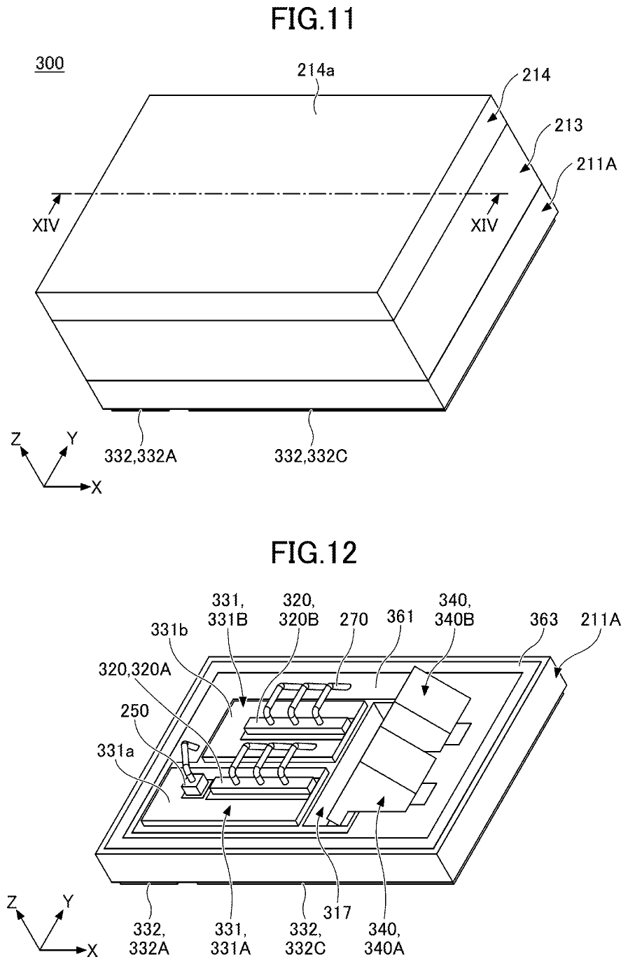

Subsequently, a light emitting device 300 according to a second embodiment will be described with reference to FIG. 11 through FIG. 15. The light emitting device 300 according to the second embodiment differs from the light emitting device 200 according to the first embodiment in that the light emitting device 300 includes a plurality of light emitting elements 320, one or more reflective members 340, and a plurality of metal parts 331, and further, a base 211A has a recess 317.

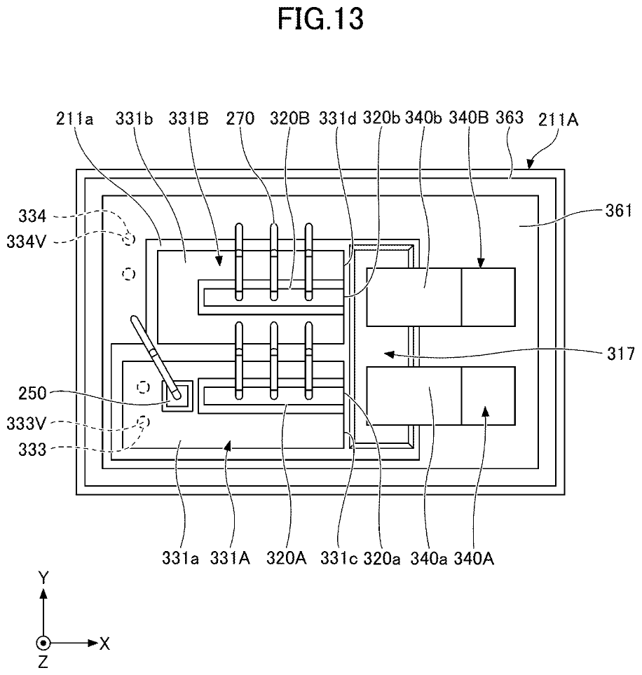

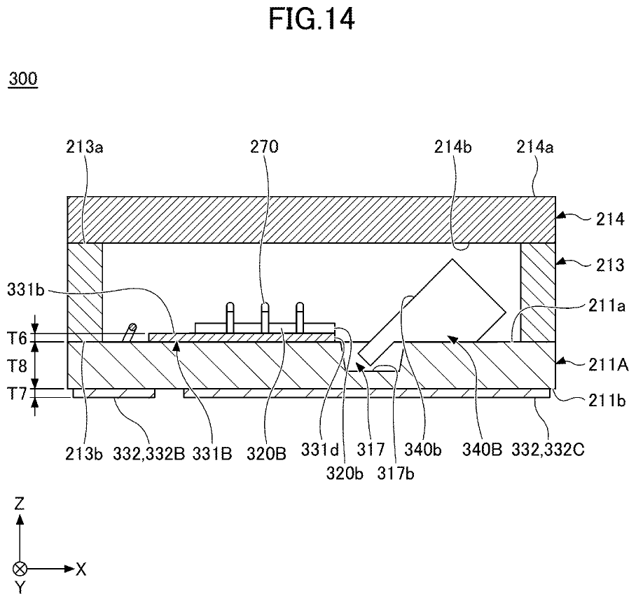

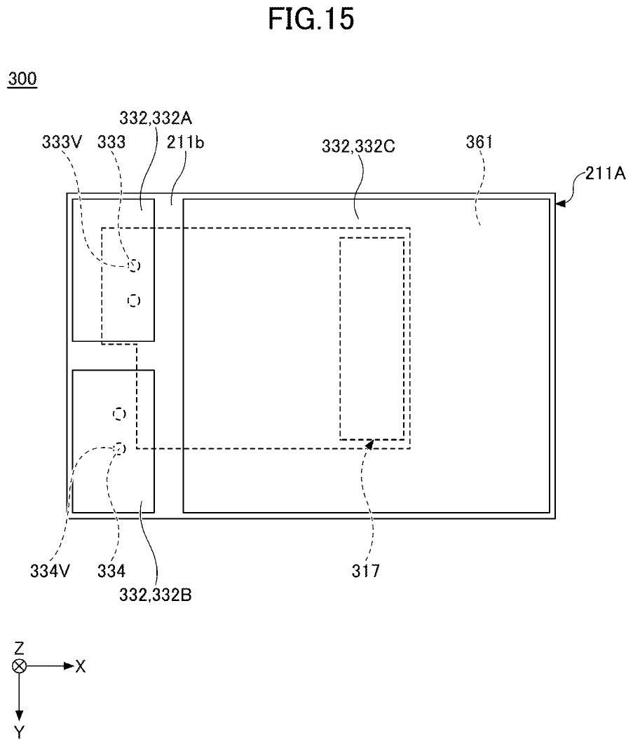

FIG. 11 is a perspective view of the light emitting device 300 according to the second embodiment. FIG. 12 is a perspective view of the light emitting device 300 illustrated in FIG. 11, from which lateral walls 213 and a cover 214 are removed. FIG. 13 is a top view of the light emitting device 300 illustrated in FIG. 11, from which the lateral walls 213 and the cover 214 are removed. FIG. 14 is a cross-sectional view of the light emitting device 300 taken through a cross-sectional line XIV-XIV of FIG. 11. FIG. 15 is a bottom view of the light emitting device 300 according to the second embodiment.

First, members will be described. The description of members shared with the first embodiment will be omitted as appropriate.

### (Base 211A)

The base 211A has an upper surface 211a, a lower surface 211b, and the recess 317. The recess 317 is open to the upper surface 211a. The recess 317 is defined by a bottom surface 317b and one or more lateral surfaces. The one or more lateral surfaces of the recess 317 meet the upper surface 211a and extend downward from the upper surface 211a. The shape of the recess 317 in a top view is, for example, a rectangle, and the length of the rectangle in the second direction Y is greater than the length of the rectangle in the first direction X. The length of the recess 317 in the second direction Y may be three times or more the length of the recess 317 in the first direction X.

The bottom surface 317b and the upper surface 211a may or may not be parallel to each other. The surface roughness of the bottom surface 317b may be greater than the surface roughness of the upper surface 211a. The one or more lateral surfaces of the recess 317 may be inclined with respect to the bottom surface 317b or may be perpendicular to the bottom surface 317b. The inclination angle of the individual lateral surfaces with respect to the bottom surface 317b is, for example, 60 degrees or more and 90 degrees or less.

### (Plurality of Light Emitting Elements 320)

Similar to the light emitting element 220 according to the first embodiment, the light emitting elements 320 are, for example, semiconductor laser elements. The light emitting elements 320 include a first light emitting element 320A and a second light emitting element 320B. The first light emitting element 320A and the second light emitting element 320B may emit light of the same color or may emit light of different colors from each other. The light emitting elements 320 are not limited to semiconductor laser elements, and may be, for example, light emitting diodes (LEDs), organic light emitting diodes (OLEDs), or the like. The number of light emitting elements 320 is not limited to two. In addition to the first light emitting element 320A and the second light emitting element 320B, additional light emitting element(s) may be further included.

### (One or More Reflective Members 340)

The one or more reflective members 340 can have a structure the same as or similar to the reflective member 240 illustrated in FIG. 7 according to the first embodiment. For example, if the light emitting device 300 includes a plurality of reflective members 340, the outer shape and the material of each of the reflective members 340 can be the same as those of the reflective member 240. In the illustrated example, the reflective members 340 include a first reflective member 340A and a second reflective member 340B. The light emitting device 300 may include one reflective member 340. In this case, a reflective member having a reflective surface 340a whose sides are longer than the reflective member 240 can be used.

### (First Metal Part 331A and Second Metal Part 331B)

A first metal part 331A and a second metal part 331B are provided on the upper surface 211a of the base 211A, and are spaced apart from each other. A thickness T6 of the second metal part 331B can be, for example, 30 μm or more and 120 μm or less. The thickness of the first metal part 331A can be the same as the thickness of the second metal part 331B. The material of each of the first metal part 331A and the second metal part 331B can be the same as the material of the metal part 231 of the first embodiment, for example.

Each of the first metal part 331A and the second metal part 331B of the illustrated light emitting device 300 has a rectangular shape in a top view. The first metal part 331A is longer than the second metal part 331B in the long side direction of the upper surface 211a of the base 211A (in the first direction X). The first metal part 331A is shorter than the second metal part 331B in the short side direction of the upper surface 211a (in the second direction Y). In the illustrated example, the first metal part 331A extends further than the second metal part 331B on the negative side in the second direction Y. A third via wiring 333V is provided in a through hole 333 penetrating the base 211A, and is connected to the first metal part 331A at a third connecting portion.

### (Lower Metal Parts 332)

One or more lower metal parts 332 may be provided on the lower surface 211b of the base 211A. A thickness T7 of each of the lower metal parts 332 is less than a thickness T8 of the base 211A. Further, the thickness T7 of each of the lower metal parts 332 is preferably 0.8 times or more and 1.2 times or less the thickness T6 of the metal part 331. The thickness T7 is preferably the same as the thickness T6. Accordingly, the same effects as in the lower metal parts 232 according to the first embodiment can be obtained.

In the illustrated example, a plurality of lower metal parts 332 including a first lower metal part 332A, a second lower metal part 332B, and a third lower metal part 332C are provided on the lower surface 211b of the base 211A. As illustrated in FIG. 15, the first lower metal part 332A and the second lower metal part 332B are both located close to one of the two short sides of the lower surface 211b in a bottom view. Further, the first lower metal part 332A and the second lower metal part 332B face each other in the short side direction of the base 211A (in the second direction Y). In the illustrated example, the first lower metal part 332A is located on the negative side in the first direction X and on the negative side in the second direction Y. The second lower metal part 332B is located on the negative side in the first direction X, and is located on the positive side in the second direction relative to the first lower metal part 332A. The first lower metal part 332A and the second lower metal part 332B may have the same size in the first direction X and the second direction Y.

In a bottom view, the third lower metal part 332C faces the first lower metal part 332A and the second lower metal part 332B in the long side direction of the lower surface 211b (in the first direction X). More specifically, the third lower metal part 332C is disposed on the positive side in the first direction X, and faces the first lower metal part 332A and the second lower metal part 332B in the first direction X. Further, in a bottom view, the third lower metal part 332C is spaced apart from the first lower metal part 332A and the second lower metal part 332B in the first direction X. The third lower metal part 332C is longer than the first lower metal part 332A and the second lower metal part 332B in the long side direction of the lower surface 211b (in the first direction X) and the short side direction of the lower surface 211b (in the second direction Y). Further, in a bottom view, the area of the third lower metal part 332C is larger than the total area of the first lower metal part 332A and the second lower metal part 332B. In order to improve heat dissipation, the area of the third lower metal part 332C is preferably larger than one-half of the area of the lower surface 211b of the base 211A.

In a top view (or in a bottom view), the first lower metal part 332A does not overlap with the recess 317. Similarly, the second lower metal part 332B does not overlap with the recess 317 in a top view. The third lower metal part 332C overlaps with at least a portion of the recess 317 in a top view. In the illustrated example, the third lower metal part 332C overlaps with the entire recess 317 in a top view.

### (Metal Film 361)

A metal film 361 is provided on the upper surface 211a of the base 211A. The thickness of the metal film 361 may be the same as the thickness of the metal film 261 of the first embodiment. Further, a metal adhesive 363 is provided on the upper surface of the metal film 361. For example, AuSn can be used as the metal adhesive 363. In a top view, the metal film 361 is provided so as to surround the first metal part 331A, the second metal part 331B, and the recess 317. In a top view, the metal film 361 does not overlap with the first metal part 331A, the second metal part 331B, and the recess 317.

A fourth via wiring 334V is provided in a through hole 334 penetrating the base 211A, and is connected to the metal film 361 at a fourth connecting portion. In a top view, the fourth connecting portion does not overlap with the first metal part 331A. In a top view, the fourth connecting portion does not overlap with the second metal part 331B.

The third via wiring 333V connected to the first metal part 331A is connected to the first lower metal part 332A. In a bottom view, the third connecting portion overlaps with the first lower metal part 332A. Further, the fourth via wiring 334V connected to the metal film 361 is connected to the second lower metal part 332B. In a bottom view, the fourth connecting portion overlaps with the second lower metal part 332B. No via wiring may be connected to the third lower metal part 332C. In a bottom view, the third connecting portion does not overlap with the third lower metal part 332C. In a bottom view, the fourth connecting portion does not overlap with the third lower metal part 332C. The third lower metal part 332C may be electrically floated.

### (Light Emitting Device 300)

Subsequently, the light emitting device 300 will be described.

The first light emitting element 320A is disposed on the upper surface 211a of the base 211A with the first metal part 331A interposed therebetween, and the second light emitting element 320B is disposed on the upper surface 211a of the base 211A with the second metal part 331B interposed therebetween. The first light emitting element 320A and the second light emitting element 320B emit light laterally from a first emission end surface 320a and a second emission end surface 320b, respectively. The first emission end surface 320a and the second emission end surface 320b face the same direction. In the illustrated example, the optical axis of light emitted from the first light emitting element 320A and the optical axis of light emitted from the second light emitting element 320B can be parallel to each other. Further, the first emission end surface 320a and the second emission end surface 320b can be parallel to each other. As used herein, the term “parallel” means that a tolerance of ±5 degrees is allowed. The distance between the first emission end surface 320a and the second emission end surface 320b in the optical axis direction of the light emitted from the first light emitting element 320A (in the first direction X) can be, for example, 50 μm or less. Further, the first emission end surface 320a and the second emission end surface 320b can be parallel to/perpendicular to, for example, one inner lateral surface or one outer lateral surface of the lateral walls 213.

The length of the first metal part 331A is greater than the length of the second metal part 331B in the first direction X. Further, the length of the first light emitting element 320A and the length of the second light emitting element 320B are less than the length of the second metal part 331B in the first direction X. Further, the difference between the length of the first light emitting element 320A and the length of the second light emitting element 320B in the first direction X is, for example, 50 μm or less. The distance between the lateral surface on the first reflective member 340A side of the first metal part 331A and the lateral surface on the second reflective member 340B side of the second metal part 331B in the first direction X is, for example, 100 μm or less. Further, the distance between the lateral surface on the opposite side of the first metal part 331A from the first reflective member 340A and the lateral surface on the opposite side of the second metal part 331B from the second reflective member 340B in the first direction X is, for example, 200 μm or more.

The first reflective member 340A and the second reflective member 340B are arranged in a same plane on the upper surface 211a of the base 211A and face the first light emitting element 320A and the second light emitting element 320B, respectively, with the recess 317 interposed therebetween. A reflective surface 340a of the first reflective member 340A faces the first emission end surface 320a of the first light emitting element 320A. A reflective surface 340b of the second reflective member 340B faces the second emission end surface 320b of the second light emitting element 320B. The reflective surface 340a and the reflective surface 340b upwardly reflect the light emitted from the first light emitting element 320A and the second light emitting element 320B, respectively.

At least a portion of each of the reflective surfaces 340a and 340b overlaps with the recess 317 in a top view. In addition, at least a portion of the lower surface of each of the first reflective member 340A and the second reflective member 340B overlaps with the recess 317 in a top view. The lower end of each of the reflective surfaces 340a and 340b is located lower than the upper surface 211a of the base 211A and higher than the bottom surface 317b of the recess 317 in a direction normal to the upper surface 211a. Further, at least a portion of the inclined surface of each of the first reflective member 340A and the second reflective member 340B is located in the recess 317 in whole or part. The lower end of each of the first reflective member 340A and the second reflective member 340B is preferably spaced apart from any of the surfaces defining the recess 317 in the third direction Z.

As described, in the light emitting device 300, a portion of the reflective surface 340a of the first reflective member 340A and a portion of the reflective surface 340b of the second reflective member 340B are disposed in the recess 317. Accordingly, the same effects as those of the first embodiment can be obtained. Further, the lower end of each of the first reflective member 340A and the second reflective member 340B is located higher than the bottom surface 317b of the recess 317. Accordingly, the same effects as those of the first embodiment can be obtained. The base 211A may have a first recess in which a portion of the first reflective member 340A is disposed, and a second recess in which a portion of the second reflective member 340B is disposed.

Large portions of the first reflective member 340A and the second reflective member 340B overlap with each other in a lateral view. More specifically, the distance between the end point on the first light emitting element 320A side of the first reflective member 340A and the end point on the second light emitting element 320B side of the second reflective member 340B in the first direction X is, for example, 50 μm or less. By arranging the reflective members as described above, the difference between the distance that the light emitted from the first light emitting element 320A travels until reaching the reflective surface 340a and the distance that the light emitted from the second light emitting element 320B travels until reaching the reflective surface 340b can be reduced. For example, the optical path lengths of the light emitted from the first light emitting element 320A and the light emitted from the second light emitting element 320B can be made uniform.

The second metal part 331B has a lateral surface 331d facing the second reflective member 340B. The lateral surface 331d faces the same direction as the second emission end surface 320b. The second metal part 331B is spaced apart from the first metal part 331A in a direction (the second direction Y) perpendicular to the optical axis direction. The lateral surface 331d can be parallel to a lateral surface 331c of the first metal part 331A. The distance between the lateral surface 331c and the lateral surface 331d in the first direction X can be 50 μm or less.

As illustrated in FIG. 12 and FIG. 13, one end of a wiring 270 is bonded to the upper surface of the light emitting element 320A, and the other end of this wiring 270 is bonded to the upper surface 331b of the second metal part 331B. For example, a plurality of wirings 270 are bonded to the second metal part 331B. In the illustrated example, three wirings 270 are bonded to the second metal part 331B. In addition, one end of a wiring 270 is bonded to the second light emitting element 320B, and the other end of this wiring 270 is bonded to the upper surface of the metal film 361 on which the first reflective member 340A and the second reflective member 340B are disposed. For example, a plurality of wirings 270 is bonded to the upper surface of the metal film 361. In the illustrated example, three wirings 270 are bonded to the upper surface of the metal film 361. Further, a wiring 270 electrically connected to the protective element 250 is bonded to the upper surface of the metal film 361. As described, the wiring 270 electrically connected to the protective element 250 is connected to the metal film 361 instead of the second metal part 331B. With this configuration, the protective element 250 is connected in parallel to the two light emitting elements 320 that are electrically connected in series. Therefore, the two light emitting elements 320 can be protected from a forward bias current or a reverse bias current.

Of the light emitted from the first light emitting element 320A, the main portion of the light travels laterally and is incident on the reflective surface 340a of the first reflective member 340A. The light incident on the reflective surface 340a is reflected upward with respect to the first reflective member 340A, is transmitted through the light transmitting region of the cover 214, and exits to the outside of the light emitting device 300. Similarly, of the light emitted from the second light emitting element 320B, the main portion of the light travels laterally and is incident on the reflective surface 340b of the second reflective member 340B. The light incident on the reflective surface 340b is reflected upward with respect to the second reflective member 340B, is transmitted through the light transmitting region of the cover 214, and exits to the outside of the light emitting device 300.

The light emitting devices 200 and 300 can be used for, for example, projectors. However, the use of the light emitting devices 200 and 300 is not limited thereto, and the light emitting devices 200 and 300 can be used for light sources for lightings, on-vehicle headlights, head-mounted displays, backlights of other displays, or the like.

According to embodiments of the present disclosure, a light emitting device in which a light emitting element(s) and a reflective member(s) can be arranged with high accuracy can be provided.

Although embodiments and the like have been described in detail above, the present disclosure is not limited to the above-described embodiments and the like, and various modifications and substitutions can be made to the above-described embodiments and the like without departing from the scope recited in the claims.

What is claimed is:

1. A light emitting device comprising:
a base having a recess and a flat upper surface;
a light emitting element disposed on the upper surface of the base and configured to emit light laterally from an emission end surface; and
a reflective member disposed on the upper surface of the base to face the light emitting element with the recess located between part of the reflective member and the light emitting element in a top view, the reflective member having a reflective surface configured to reflect the light upward; wherein:
at least a portion of the reflective surface overlaps with the recess in the top view, and
a lower end of the reflective surface is located lower than the upper surface of the base and higher than a bottom surface of the recess in a direction normal to the upper surface of the base.

2. The light emitting device according to claim 1, wherein:
the reflective member has a lower surface located on the upper surface of the base; and
the reflective surface is inclined with respect to the lower surface, and a portion of the reflective surface is located lower than a lowest point of the lower surface in the direction normal to the upper surface of the base.

3. The light emitting device according to claim 2, wherein:
at least a portion of the lower surface of the reflective member overlaps with the recess in the top view; and
the light emitting element does not overlap with the recess in the top view.

4. The light emitting device according to claim 2, wherein:
the reflective member has an inclined surface opposite the reflective surface, and at least a portion of the inclined surface is located in the recess, connected to the lower surface, and inclined with respect to the lower surface.

5. The light emitting device according to claim 4, wherein:
the inclined surface is parallel to the reflective surface; and
an area of the inclined surface is less than one-half of an area of the lower surface.

6. The light emitting device according to claim 1, wherein:
the recess is defined by the bottom surface and one or more lateral surfaces;
the one or more lateral surfaces of the recess meet the upper surface of the base and extend downward from the upper surface of the base; and
a lower end of the reflective member is spaced apart from the bottom surface and/or the one or more lateral surfaces defining the recess.

7. The light emitting device according to claim 6, wherein the one or more lateral surfaces are inclined with respect to the bottom surface of the recess, and an inclination angle of at least one of the lateral surfaces with respect to the bottom surface is larger than an inclination angle of the reflective surface with respect to the bottom surface.

8. The light emitting device according to claim 1, wherein a point at which an optical axis of the light meets the reflective surface is located lower than a center point of the reflective surface in the direction normal to the upper surface of the base.

9. The light emitting device according to claim 1, wherein:
a center point of the reflective surface is located higher than the upper surface of the base; and
an area of a portion of the reflective surface located higher than the recess is larger than an area of a portion of the reflective surface located in the recess in the direction normal to the upper surface of the base.

10. The light emitting device according to claim 1, wherein a length from the bottom surface of the recess to the upper surface of the base is six times or less a thickness of the light emitting element in the direction normal to the upper surface of the base.

11. The light emitting device according to claim 1, further comprising:
a metal part that is interposed between the upper surface of the base and the light emitting element; wherein:
the metal part has a lateral surface that faces a same direction as the emission end surface;
the lateral surface of the metal part does not overlap with the recess in the top view; and
a distance between the lateral surface of the metal part and the emission end surface in a direction perpendicular to the emission end surface is 50 μm or less.

12. The light emitting device according to claim 11, wherein a distance between a point of the recess closest to the light emitting element and the lateral surface of the metal part in the direction perpendicular to the emission end surface is 0 μm or more and 150 μm or less.

13. The light emitting device according to claim 1, further comprising:
one or more lateral walls that extend upward from the upper surface of the base; and
a cover disposed on the one or more lateral walls; wherein:
the cover has a light incident surface on which the light reflected by the reflective surface is incident; and
a difference between a length from the light incident surface to the upper surface of the base and a length from an upper end to a lower end of the reflective surface in the direction normal to the upper surface of the base is 200 μm or less.

14. The light emitting device according to claim 1, wherein the reflective member includes silicon as a main material.
